(19) United States
(12) Patent Application Publication
(10) Pub. No.: US 2023/0215708 A1
(43) Pub. Date: Jul. 6, 2023

(54) SUBSTRATE SUPPORT UNIT AND PLASMA PROCESSING APPARATUS

(71) Applicant: SEMES CO., LTD., Cheonan-si (KR)

(72) Inventors: Dongchan LEE, Anseong-si (KR); Jaekyung LEE, Cheonan-si (KR); Jiseok KIM, Seoul (KR); Jehee LEE, Uijeongbu-si (KR); Kiryong LEE, Pyeongtaek-si (KR)

(73) Assignee: SEMES CO., LTD., Cheonan-si (KR)

(21) Appl. No.: 18/148,044

(22) Filed: Dec. 29, 2022

(30) Foreign Application Priority Data
Dec. 31, 2021 (KR) 10-2021-0194111

(51) Int. Cl. H01J 37/32

(52) U.S. Cl. CPC H01J 37/32724; H01J 37/32642; H01J 2237/2007; H01J 2237/002; H01J 2237/334; H01L 21/6833

(57) ABSTRACT

Provided is a substrate support unit including an electrostatic chuck configured to fix a wafer, an insulating isolation unit, which is arranged below the electrostatic chuck and is configured to insulate the electrostatic chuck, and a ground plate arranged below the insulating isolation unit, wherein the electrostatic chuck, the insulating isolation unit, and the ground plate are spaced apart from each other in a vertical direction, and a lower surface of the electrostatic chuck, a surface of the insulating isolation unit, or a surface of the ground plate has hydrophobicity.

### CROSS-REFERENCE TO RELATED APPLICATION

This application is based on and claims priority under 35 U.S.C. § 119 to Korean Patent Application No. 10-2021-0194111, filed on Dec. 31, 2021, in the Korean Intellectual Property Office, the disclosure of which is incorporated by reference herein in its entirety.

### BACKGROUND

### 1. Field

The disclosure relates to a substrate support unit and a plasma processing apparatus including the substrate support unit, and more particularly, to a substrate support unit capable of preventing the occurrence of dew condensation in a plasma chamber, and a plasma processing apparatus including the substrate support unit.

### 2. Description of the Related Art

In a plasma chamber in which a semiconductor process is performed on a substrate by using plasma, the substrate is controlled at a preset temperature. Because the substrate is heated by plasma, it is necessary to cool the substrate in order to maintain the temperature of the substrate at the preset temperature during the semiconductor process using plasma. For example, a substrate support unit may be provided such that the substrate is cooled by circulating a refrigerant having a temperature lower than the room temperature in the substrate support unit in which the substrate is placed.

However, the temperature of the substrate support unit may become lower than the room temperature due to the refrigerant circulating therein, and thus, dew condensation may occur at a portion in contact with the outside air. In addition, the temperature of other components in contact with the substrate support unit may also decrease, resulting in dew condensation. When dew condensation occurs in the substrate support unit, the reliability of the plasma processing apparatus may be lowered due to moisture formed by the dew condensation.

### SUMMARY

Provided is a substrate support unit capable of preventing the occurrence of dew condensation in a plasma chamber.

Provided is a plasma processing apparatus including the substrate support unit capable of preventing the occurrence of dew condensation in a plasma chamber.

Additional aspects will be set forth in part in the description which follows and, in part, will be apparent from the description, or may be learned by practice of the presented embodiments of the disclosure.

According to an aspect of the disclosure, a substrate support unit includes an electrostatic chuck configured to fix a wafer, an insulating isolation unit, which is arranged below the electrostatic chuck and is configured to insulate the electrostatic chuck, and a ground plate arranged below the insulating isolation unit, wherein the electrostatic chuck, the insulating isolation unit, and the ground plate are spaced apart from each other in a vertical direction, and a lower surface of the electrostatic chuck, a surface of the insulating isolation unit, or a surface of the ground plate has hydrophobicity.

According to another aspect of the disclosure, a substrate support unit includes an electrostatic chuck configured to fix a wafer, an edge ring, which surrounds the electrostatic chuck and has a ring shape, an insulating isolation unit, which surrounds the electrostatic chuck and the edge ring and is configured to insulate the electrostatic chuck, a sealing member arranged between a side surface of the edge ring and a side surface of the insulating isolation unit, and a ground plate arranged below the insulating isolation unit, wherein the electrostatic chuck, the insulating isolation unit, and the ground plate are spaced apart from each other in a vertical direction, and a surface of the insulating isolation unit has hydrophobicity.

According to another aspect of the disclosure, a plasma processing apparatus includes a plasma chamber, an electrostatic chuck, which is arranged inside the plasma chamber and is configured to fix a wafer, an edge ring, which surrounds the electrostatic chuck and has a ring shape, an insulating isolation unit, which is arranged below the electrostatic chuck and is configured to insulate the electrostatic chuck, and a ground plate arranged below the insulating isolation unit, wherein the electrostatic chuck, the insulating isolation unit, and the ground plate are spaced apart from each other in a vertical direction to form an air gap, a refrigerant or clean dry air is circulated in the air gap, and a lower surface of the electrostatic chuck, a surface of the insulating isolation unit, and a surface of the ground plate each have hydrophobicity.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a plasma processing apparatus according to an embodiment;

FIG. 2A is a side view schematically illustrating the state in which water droplets are on the surface of a solid on which hydrophobic treatment is not performed, FIG. 2B is a side view schematically illustrating the state in which water droplets are on the surface of a solid on which hydrophobic treatment is performed, and FIG. 2C is a side view schematically illustrating the state in which water droplets are on the surface of a solid on which superhydrophobic treatment is performed;

FIG. 3 is a perspective view illustrating the surface of a solid or ceramic having hydrophobicity;

FIG. 4 is a configuration diagram illustrating a plasma processing apparatus according to another embodiment;

FIG. 5 is a configuration diagram illustrating a plasma processing apparatus according to another embodiment; and

FIG. 6 is a configuration diagram illustrating a plasma processing apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The same reference numerals are used for the same components in the drawings, and redundant descriptions thereof will be omitted.

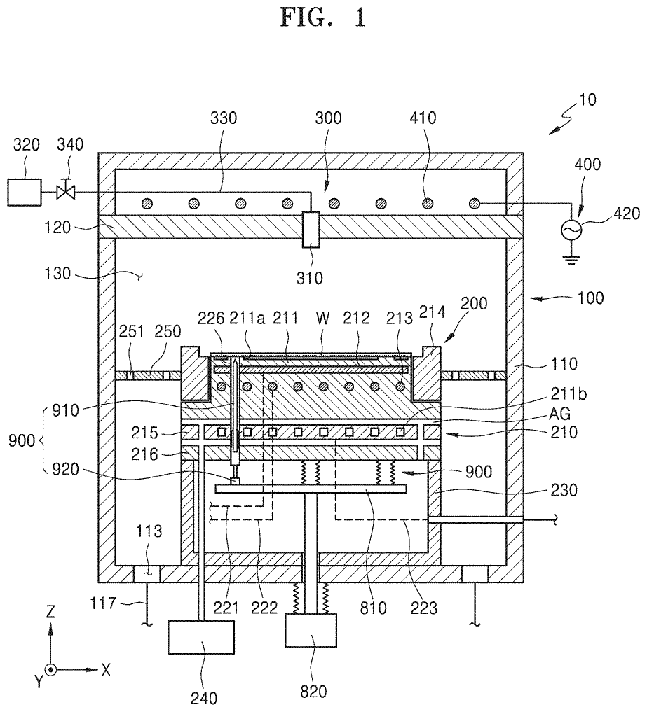

FIG. 1 is a cross-sectional view illustrating a plasma processing apparatus 10 according to an embodiment.

Referring to FIG. 1, the plasma processing apparatus 10 may include a plasma chamber 100, a substrate support unit 200, a gas supply unit 300, and a plasma source unit 400.

The plasma chamber 100 provides a space in which plasma processing is performed, and the substrate support unit 200 supports, inside the plasma chamber 100, a substrate W. The gas supply unit 300 supplies process gas into the plasma chamber 100, and the plasma source unit 400 generates plasma from the process gas by providing electromagnetic waves to the inside of the plasma chamber 100. Hereinafter, each component will be described in detail.

The plasma chamber 100 includes a chamber body 110 and a dielectric cover 120. The upper surface of the chamber body 110 is open, and a space is formed in the chamber body 110. An exhaust hole 113 is formed in the floor of the chamber body 110. The exhaust hole 113 is connected to an exhaust line 117 and provides a passage through which gas remaining inside the chamber body 110 and reaction by-products formed during a process are discharged to the outside. A plurality of exhaust holes 113 may be formed in edges of the floor of the chamber body 110.

The dielectric cover 120 seals the open upper surface of the chamber body 110. The dielectric cover 120 has a radius corresponding to the circumference of the chamber body 110. The dielectric cover 120 may be made of a dielectric material. The dielectric cover 120 may be made of aluminum. A space surrounded by the dielectric cover 120 and the chamber body 110 is provided as a processing space 130 in which plasma processing is performed.

A baffle 250 controls the flow of the process gas inside the plasma chamber 100. The baffle 250 is provided in a ring shape and is positioned between the plasma chamber 100 and the substrate support unit 200. Distribution holes 251 are formed in the baffle 250. The process gas remaining in the plasma chamber 100 passes through the distribution holes 251 and then flows into the exhaust hole 113. The flow of the process gas introduced into the exhaust hole 113 may be controlled according to the shape and arrangement of the distribution holes 251.

The gas supply unit 300 is configured to supply the process gas into the plasma chamber 100. The gas supply unit 300 includes a nozzle 310, a gas storage unit 320, and a gas supply line 330.

The nozzle 310 is mounted on the dielectric cover 120. The nozzle 310 may be positioned at the center of the dielectric cover 120. The nozzle 310 is connected to the gas storage unit 320 through the gas supply line 330. A valve 340 is installed in the gas supply line 330. The valve 340 opens and closes the gas supply line 330 and adjusts the supply flow rate of the process gas. The process gas stored in the gas storage unit 320 is supplied to the nozzle 310 through the gas supply line 330 and is injected from the nozzle 310 into the plasma chamber 100. The nozzle 310 mainly supplies the process gas to the center of the processing space 130. Alternatively, the gas supply unit 300 may further include a nozzle (not shown) mounted on a sidewall of the chamber body 110. The nozzle supplies the process gas to an edge region of the processing space 130.

The plasma source unit 400 generates plasma from the process gas. The plasma source unit 400 includes an antenna 410 and a power source 420. The plasma source unit 400 may be configured to generate plasma. The plasma source unit 400 may include a capacitively coupled plasma (CCP) source, an inductively coupled plasma (ICP) source, a microwave plasma source, a remote plasma source, and the like.

The antenna 410 is provided at an upper portion of the plasma chamber 100. The antenna 410 may be provided as a spiral coil. The power source 420 is connected to the antenna 410 through a cable and applies high-frequency electric power to the antenna 410. Electromagnetic waves are generated in the antenna 410 as the high-frequency electric power is applied. The electromagnetic waves form an induced electric field inside the plasma chamber 100. The process gas is changed to plasma by obtaining energy required for ionization from the induced electric field. The plasma is applied to the substrate W, and an etching process may be performed.

The substrate support unit 200 is positioned in the processing space 130 and supports the substrate W. The substrate support unit 200 may fix the substrate W by using electrostatic force, or may support the substrate W by using a mechanical clamping method. Hereinafter, an example will be described in which the substrate support unit 200 fixes the substrate W by using electrostatic force.

The substrate support unit 200 includes a susceptor 210, a housing 230, and a lift pin structure 900.

The susceptor 210 adsorbs the substrate by using electrostatic force. The susceptor 210 may include an electrostatic chuck 211, an electrode 212, heaters 213, an edge ring 214, an insulating isolation unit 215, and a ground plate 216.

The electrostatic chuck 211 is provided in a circular plate shape. The upper surface of the electrostatic chuck 211 may have a radius corresponding to or less than that of the substrate W. For example, the electrostatic chuck 211 may be formed of ceramic, such as aluminum oxide (Al₂O₃) or aluminum nitride (AlN).

Protrusions 211a may be formed on the upper surface of the electrostatic chuck 211. The substrate W is placed on the protrusions 211a and is spaced apart from the upper surface of the electrostatic chuck 211 by a preset distance. The electrostatic chuck 211 may have a stepped side surface such that a lower region thereof has a radius greater than that of an upper region.

The electrode 212 is buried in the electrostatic chuck 211. The electrode 212 is a thin circular plate made of a conductive material, and is connected to an external power source (not shown) through a cable 221. Electric power applied from the external power source forms an electrostatic force between the electrode 212 and the substrate W to fix the substrate W to the upper surface of the electrostatic chuck 211. The external power source may be a direct current (DC) power source or a radio frequency (RF) power source.

The heaters 213 are provided inside the electrostatic chuck 211. The heaters 213 may be provided below the electrode 212. The heaters 213 are connected to an external power source (not shown) through a cable 222. The heaters 213 generate heat by resisting a current applied from the external power source. The generated heat is transferred to the substrate W through the electrostatic chuck 211, and heats the substrate W to a preset temperature. The heaters 213 are provided as spiral coils, and may be buried in the electrostatic chuck 211 at regular intervals.

The edge ring 214 is provided in a ring shape and is arranged along the circumference of the upper region of the electrostatic chuck 211. The edge ring 214 may be formed of silicone, and may induce an effect of expanding a silicone region of the substrate W so as to prevent plasma from being concentrated on the edge portion of the substrate W. The upper surface of the edge ring 214 may be stepped such that an inner portion adjacent to the electrostatic chuck 211 is lower than an outer portion. An inner portion of the upper surface of the edge ring 214 may be positioned at the same height as that of the upper surface of the electrostatic chuck 211. The edge ring 214 expands a region in which the electromagnetic field is formed, such that the substrate W is positioned at the center of a region in which plasma is formed. Accordingly, the plasma may be uniformly formed over the entire region of the substrate W. Meanwhile, the edge ring 214 may be of a one-ring type or a two-ring type, and in general, the one-ring type is referred to as a focus ring and the two-ring type is referred to as a combo ring.

The insulating isolation unit 215 is positioned below the electrostatic chuck 211 and supports the electrostatic chuck 211. The insulating isolation unit 215 may be a circular plate having a preset thickness, and may have a radius corresponding to the electrostatic chuck 211. The insulating isolation unit 215 is formed of an insulating material. The insulating isolation unit 215 is connected to an external power source (not shown) through a cable 223. A high-frequency current applied to the insulating isolation unit 215 through the cable 223 forms an electromagnetic field between the substrate support unit 200 and the dielectric cover 120. The electromagnetic field is provided as energy to generate plasma. The insulating isolation unit 215 may be formed of an insulator, such as aluminum oxide (Al₂O₃) or aluminum nitride (AlN). Of course, the material of the insulating isolation unit 215 is not limited thereto. In another embodiment, the insulating isolation unit 215 may surround the electrostatic chuck 211 and the edge ring 214.

A cooling flow path 211b may be formed in the insulating isolation unit 215. The cooling flow path 211b is positioned below the heaters 213. The cooling flow path 211b provides a passage through which cooling fluid circulates. The heat of the cooling fluid is transferred to the electrostatic chuck 211 and the substrate W, and the heated electrostatic chuck 211 and the substrate W are rapidly cooled. The cooling flow path 211b may be formed in a spiral shape. Alternatively, the cooling flow path 211b may be arranged such that ring-shaped flow paths having different radii have the same center. The flow paths may communicate with each other. In another embodiment, the cooling flow path 211b may be formed inside the ground plate 216.

The ground plate 216 is positioned below the insulating isolation unit 215. The ground plate 216 may be a circular plate having a preset thickness, and may have a radius corresponding to the insulating isolation unit 215. The ground plate 216 is grounded. The ground plate 216 electrically insulates the insulating isolation unit 215 from the chamber body 110. The ground plate 216 may generate plasma inside the plasma chamber 100 by maintaining an electrical ground state. In addition, the ground plate 216 may be formed of a material highly resistant to plasma, or may be formed of a metal, ceramic, or the like and coated with a material film resistant to plasma on the outer surface thereof. For example, the ground plate 216 may be formed of aluminum, copper, titanium, tungsten, zinc, or tin, and an alloy thereof. Also, the shape of the ground plate 216 may be variously modified. For example, the ground plate 216 may have a circular, elliptical, or polygonal flat shape.

A pin hole 226 is formed in the susceptor 210. The pin hole 226 is formed on the upper surface of the susceptor 210. Also, the pin hole 236 may vertically penetrate the susceptor 210. The pin hole 226 is provided from the upper surface of the electrostatic chuck 211 to the lower surface of the ground plate 216, sequentially through the electrostatic chuck 211, the insulating isolation unit 215, and the ground plate 216.

A plurality of pin holes 226 may be formed. A plurality of pin holes 226 may be arranged in the circumferential direction of the electrostatic chuck 211. For example, three pin holes 226 may be arranged to be spaced apart from each other at about 120° in the circumferential direction of the electrostatic chuck 211. In addition, various numbers of pin holes 226 may be formed, for example, four pin holes 226 may be arranged to be spaced apart from each other at about 90° in the circumferential direction of the electrostatic chuck 211.

Also, the pin hole 226 may be formed in the protrusion 211a of the electrostatic chuck 211. For example, the pin hole 226 having a circular shape may be formed at the center of the protrusion 211a having a circular planar shape. However, the planar shapes of the protrusion 211a and the pin hole 226 may be variously provided. The pin hole 226 may be formed on a part of the protrusion 211a. For example, six protrusions 211a may be arranged to be spaced apart from each other at 60° in the circumferential direction of the electrostatic chuck 211, and three pin holes 226 may be arranged to be spaced apart from each other at about 30°.

The housing 230 is positioned below the ground plate 216 and supports the ground plate 216. The housing 230 is a cylinder having a preset height, and a space is formed therein. The housing 230 may have a modification corresponding to the ground plate 216. Various cables 221, 222, and 223 and the lift pin structure 900 are positioned inside the housing 230.

The lift pin structure 900 loads the substrate W onto the electrostatic chuck 211, or unloads the substrate W from the electrostatic chuck 211, by moving upward or downward. The lift pin structure 900 includes a lift pin 910 that supports a substrate.

A plurality of lift pins 910 are provided and accommodated in the pin holes 226, respectively. Here, the diameter of the lift pin 910 is slightly less than the diameter of the pin hole 226. In detail, the diameter of the lift pin 910 may be a minimum diameter at which the lift pin 910 is not in contact with the inner wall of the pin hole 226 when the lift pin 910 and the pin hole 226 are arranged to have the same central axis.

A support plate 810 may support the lift pin structure 900. In addition, a driver 820 may be connected to the support plate 810 to drive the support plate 810 and the lift pin structure 900 in the vertical direction. However, unlike as illustrated in FIG. 1, the support plate 810 may not be provided, and the driver 820 may directly drive the lift pin structure 900 in the vertical direction. The lift pin structure 900 may include a connecting member 920 that connects the lift pin 910 and the support plate 810 to each other.

The driver 820 may move the lift pin structure 900 in the vertical direction by driving the support plate 810 in the vertical direction. That is, when driven by the driver 820, the lift pin 910 may move to the top of the pin hole 226 to perform an operation of dechucking the substrate. In addition, although FIG. 1 illustrates that the driver 820 is arranged outside the plasma chamber 100, the driver 820 may be provided inside the plasma chamber 100.

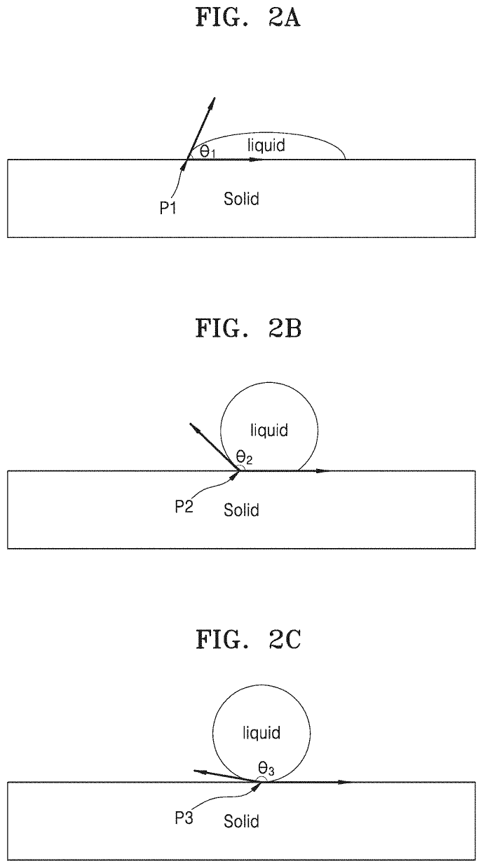

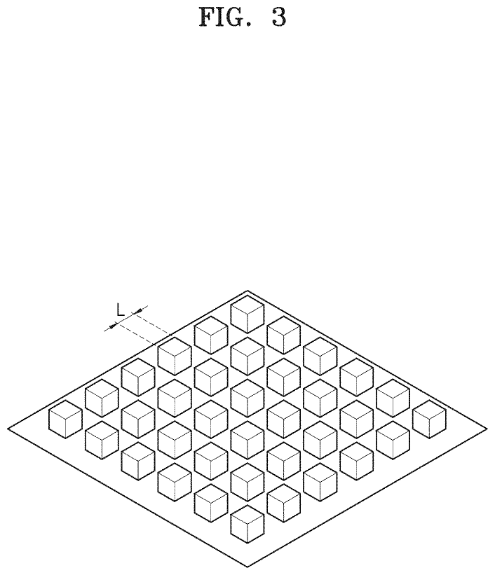

A surface of each of the electrostatic chuck 211, the insulating isolation unit 215, and/or the ground plate 216 may have hydrophobicity. For example, a surface of each of the electrostatic chuck 211, the insulating isolation unit 215, and/or the ground plate 216 may have superhydrophobicity. For example, the lower surface of the electrostatic chuck 211 may have hydrophobicity. In addition, a surface of each of the insulating isolation unit 215 and/or the ground plate 216 may have hydrophobicity. Because a refrigerant or clean dry air (CDA) is not circulated on the upper surface of the electrostatic chuck 211, hydrophobic treatment may not be necessary on the upper surface of the electrostatic chuck 211. A method of performing hydrophobic treatment on the surface of each of a plurality of devices included in the substrate support unit 200 will be described in detail with reference to FIGS. 2A to 3.

The electrostatic chuck 211, the insulating isolation unit 215, and/or the ground plate 216 may be spaced apart from each other by a preset distance in the vertical direction (i.e., a Z direction). Thus, an air gap AG may be formed inside the substrate support unit 200. A refrigerant or CDA may be distributed along the air gap AG. The CDA may be supplied from a CDA supply 240 and distributed through the air gap AG. A flow path configured to circulate the CDA may be provided in the air gap AG, and the surface of the flow path may also have hydrophobicity. In another embodiment, a refrigerant may also be circulated through the air gap AG.

In a general plasma processing apparatus, the temperature of a substrate needs to be kept constant during a semiconductor process. However, when the upper surface of the substrate is in contact with plasma, the temperature of the substrate may rise. Therefore, a low-temperature refrigerant is circulated through a substrate support unit to lower the temperature of the substrate. However, the low-temperature refrigerant is circulated through the substrate support unit, and thus, dew condensation may occur on surfaces of components included in the substrate support unit. In addition, CDA is also circulated inside the substrate support unit in order to remove moisture generated on the surface of each of the components included in the substrate support unit.

In the plasma processing apparatus 10 and the substrate support unit 200 according to the present embodiment, the surface of each component included in the substrate support unit 200 has hydrophobicity, and thus, the possibility of dew condensation occurring on the surface of each component included in the substrate support unit 200 may be relatively reduced. Accordingly, the reliability of each of the plasma processing apparatus 10 and the substrate support unit 200 may be improved. In addition, moisture on the surface of each component included in the substrate support unit 200 is relatively reduced, the required flow rate of CDA may also be relatively reduced.

For example, the lower surface of the electrostatic chuck 211, the surface of the insulating isolation unit 215, and/or the surface of the ground plate 216 may have hydrophobicity.

FIG. 2A is a side view schematically illustrating the state in which water droplets are on the surface of a solid on which hydrophobic treatment is not performed, FIG. 2B is a side view schematically illustrating the state in which water droplets are on the surface of a solid on which hydrophobic treatment is performed, and FIG. 2C is a side view schematically illustrating the state in which water droplets are on the surface of a solid on which superhydrophobic treatment is performed.

Referring to FIGS. 2A to 2C, water droplets may be in contact with the surfaces of the solids. The water droplet on the surface of the solid on which hydrophobic treatment is not performed may have a relatively low contact angle. On the contrary, the water droplet on the surface of the solid on which hydrophobic treatment or superhydrophobic treatment is performed may have a relatively high contact angle.

In addition, wettability is a key surface property of solid materials, and may be governed primarily by chemical composition and geometrical micro/nanostructure. Wettable surfaces may be used in various fields, such as oil-water separation, anti-reflection, anti-bioadhesion, anti-cohesion, anti-fouling, self-cleaning, or fluid turbulence suppression.

For example, when the contact angle of a water droplet with respect to the surface of a solid is less than about 90°, the solid may be hydrophilic, whereas when the contact angle of a water droplet with respect to the surface of a solid is greater than or equal to about 90°, the solid may be hydrophobic. Superhydrophobicity may refer to a case in which the contact angle of a water droplet with respect to the surface of a solid is about 150° or greater. When a liquid is on the surface of a solid, the contact angle of the liquid with respect to the solid may be defined as, among the angles between a contact point P1, P2 or P3 at which the solid and the liquid is in contact with each other, and the tangent line to the contact point, the angle on the side of the liquid. That is, the contact angle may refer to, when a liquid and/or gas are in thermodynamic equilibrium on the surface of a solid, the angle between the liquid and the surface of the solid. That is, the contact angle may refer to the degree of wettability of the surface of a solid.

For example, θ₁ in FIG. 2A may be less than about 90°, θ₂ in FIG. 2B may be about 90° or greater, θ₃ in FIG. 2C may be about 150° or greater. A water droplet on the surface of a superhydrophobic solid may have a relatively more spherical shape.

A method of performing hydrophobic treatment on the surface of a solid will be described in detail with reference to FIG. 3.

FIG. 3 is a perspective view illustrating the surface of a solid or ceramic having hydrophobicity.

Referring to FIG. 3, a hydrophobic structure having a roughened structure may include a microstructure including plateaus that are substantially parallel to the surface of the hydrophobic structure, and sidewalls that are substantially perpendicular to the surface of the hydrophobic structure. Here, that the sidewalls and the plateaus are substantially perpendicular to each other does not mean that the angle between the sidewall and the plateau is about 90°, but may mean that the sidewalls, as planes connecting between the plateaus having several levels, exist to be distinguishable from the plateaus.

In addition, a plurality of sidewalls and a plurality of plateaus may be continuously arranged along the surface of the hydrophobic structure with or without a certain rule. However, the plurality of sidewalls and the plurality of plateaus do not necessarily need to be arranged over the entire surface of the hydrophobic structure, and may be arranged on only a portion of the surface of the hydrophobic structure that requires hydrophobicity.

In addition, the length of the plateau in the horizontal direction may be defined as a distance L between two outermost points in the edges of the defined plateau, and the length in the horizontal direction may be about 100 nm to about 5 μm.

FIG. 3 exemplarily illustrates that the hydrophobic structure has a rectangular parallelepiped shape, but the shape of the hydrophobic structure is not limited thereto. For example, the hydrophobic structure may have a spherical shape, a polygonal prism shape, and/or various irregular shapes.

Hydrophobicity may be imparted to the surface of a metal substrate through anodization. Methods for anodization are well known to those of skill in the art. For example, the metal substrate is immersed in a sulfuric acid solution, an oxalic acid solution, a citric acid solution, a sodium nitrate solution, a sodium chloride solution, a chromic acid solution, or a phosphoric acid solution, and a voltage is applied by using the metal substrate as an anode. The voltage may be about 10 V to about 30 V. The anodization may be performed at room temperature for about 1 minute to about 30 minutes. The voltage, temperature, and time described above are examples, and may be variously modified depending on the material or size of the metal substrate. The hydrophobic structure formed by performing anodization on the surface of the metal substrate may be formed of aluminum oxide, copper oxide, titanium oxide, tungsten oxide, zinc oxide, and/or tin oxide. The material of the hydrophobic structure may vary depending on the material of the metal substrate.

In addition, by coating the surface of ceramic with the hydrophobic structure, the surface of the ceramic may have hydrophobicity. For example, the hydrophobic structure may be deposited on the surface of the ceramic by performing laser ablation, deposition coating through a colloidal process, and/or conformal coating using a thin film or a laser. For example, the thickness of the coating may be about 200 nm to about 350 nm. For example, the ceramic may include CeO₂, Pr₆O₁₁, Nd₂O₃, Sm₂O₃, Eu₂O₃, Gd₂O₃, Tb₄O₇, Dy₂O₃, Ho₂O₃, Er₂O₃, Tm₂O₃, Yb₂O₃, and/or Lu₂O₃.

In another embodiment, when fluorination is performed on the surface of a solid and/or ceramic, the surface may have hydrophobicity. The method of performing hydrophobic treatment on the surface of a solid and/or ceramic described above is an example, and various methods of performing hydrophobic treatment on the surface of a solid and/or ceramic may be adopted.

The surface of an unprocessed solid or ceramic may be relatively flat. Accordingly, the surface of the unprocessed solid or ceramic may have relatively high wettability, and thus may be relatively more hydrophilic. Thus, when a water droplet is on the surface of the unprocessed solid or ceramic, the contact angle may be less than about 90°, and the shape of the water droplet may be relatively more elliptical.

Although it is described above with reference to FIG. 3 that the surface of a solid or ceramic is processed and thus has hydrophobicity, this is an example, and the type of metal or ceramic to be processed may be variously modified.

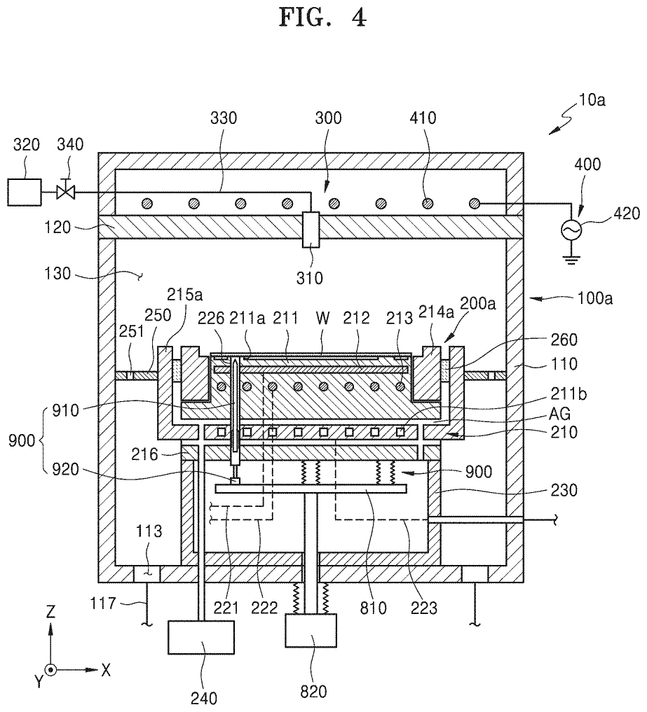

FIG. 4 is a configuration diagram illustrating a plasma processing apparatus 10a according to another embodiment.

Referring to FIGS. 1 and 4 together, a substrate support unit 200a of the present embodiment may be different from the substrate support unit 200 of FIG. 1 in that the substrate support unit 200a further includes a sealing member 260. In addition, referring to FIGS. 1 and 4 together, the plasma processing apparatus 10a of the present embodiment may be different from the plasma processing apparatus 10 of FIG. 1 in that an insulating isolation unit 215a surrounds the electrostatic chuck 211 and the edge ring 214. In more detail, the substrate support unit 200a of the present embodiment may include the electrostatic chuck 211, an edge ring 214a, the insulating isolation unit 215a, the ground plate 216, and the sealing member 260. The electrostatic chuck 211 and the ground plate 216 are the same as the electrostatic chuck 211 and the ground plate 216 of the substrate support unit 200 of FIG. 1 described above.

CDA may be in contact with a side surface of the edge ring 214a. Accordingly, the side surface of the edge ring 214a may have hydrophobicity. In addition, CDA may be in contact with a side surface of the electrostatic chuck 211. The side surface of the electrostatic chuck 211 may also have hydrophobicity. In addition, the insulating isolation unit 215a may surround the electrostatic chuck 211 and the edge ring 214a.

The sealing member 260 may be between the electrostatic chuck 211 and the insulating isolation unit 215a. The sealing member 260 may be configured to prevent a refrigerant or CDA from moving to the top of the electrostatic chuck 211. That is, the sealing member 260 may be in direct contact with the side surface of each of the edge ring 214 and the insulating isolation unit 215a. For example, the sealing member 260 may be formed of pentafluorophenyl (PFP). According to an embodiment, the surface of the sealing member 260 may not undergo hydrophobic treatment.

According to another embodiment, the lower surface of the sealing member 260 may be in direct contact with a refrigerant or CDA, and thus may undergo hydrophobic treatment. The method of performing hydrophobic treatment may be substantially the same as that described above with reference to FIG. 3.

That is, in the substrate support unit 200a of the present embodiment, the sealing member 260 may be between the edge ring 214a and the insulating isolation unit 215a. Accordingly, the edge ring 214a and the insulating isolation unit 215a are not in direct contact with each other, and thus, the electrical stability of the substrate support unit 200a may be improved.

In addition, the uppermost surface of the insulating isolation unit 215a may be positioned to be substantially coplanar with the uppermost surface of the edge ring 214a. According to another embodiment, the uppermost surface of the insulating isolation unit 215a may be positioned at a lower vertical level than the uppermost surface of the edge ring 214a.

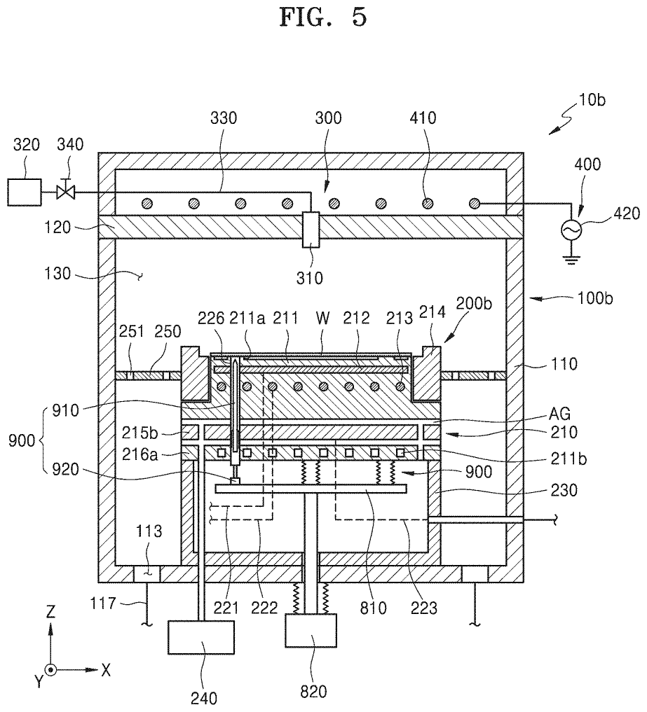

FIG. 5 is a configuration diagram illustrating a plasma processing apparatus 10b according to another embodiment.

Referring to FIG. 5, a substrate support unit 200b of the present embodiment may be different from the substrate support unit 200 of FIG. 1 in that the cooling flow path 211b is arranged inside a ground plate 216a.

Except for the arrangement position of the cooling flow path 211b, the substrate support unit 200b of the present embodiment may be substantially the same as the substrate support unit 200 of FIG. 1.

Although not illustrated in FIG. 5, an insulating isolation unit 215b may be arranged to surround the electrostatic chuck 211 and the edge ring 214. In addition, it is needless to say that the sealing member 260 may be arranged between the electrostatic chuck 211 and the insulating isolation unit 215b.

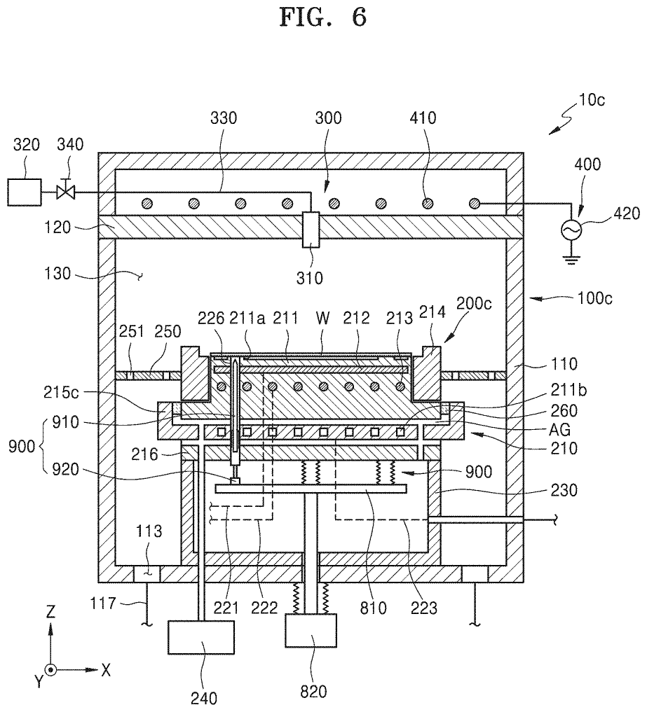

FIG. 6 is a configuration diagram illustrating a plasma processing apparatus 10c according to another embodiment.

Referring to FIGS. 1 and 6 together, a substrate support unit 200c of the present embodiment may be different from the substrate support unit 200 of FIG. 1 in that the substrate support unit 200c further includes the sealing member 260. Also, referring to FIGS. 1, 4, and 6 together, the plasma processing apparatus 10c of the present embodiment may be different from the plasma processing apparatuses 10 and 10a of FIGS. 1 and 4 in that an insulating isolation unit 215c surrounds the electrostatic chuck 211. In more detail, the substrate support unit 200c of the present embodiment may include the electrostatic chuck 211, the edge ring 214, the insulating isolation unit 215c, the ground plate 216, and the sealing member 260. The electrostatic chuck 211 and the ground plate 216 are the same as the electrostatic chuck 211 and the ground plate 216 of the substrate support unit 200 of FIG. 1 described above.

The sealing member 260 may be between the electrostatic chuck 211 and the insulating isolation unit 215c. The sealing member 260 may be configured to prevent a refrigerant or CDA from moving to the top of the electrostatic chuck 211. That is, the sealing member 260 may be in direct contact with the side surface of each of the electrostatic chuck 211 and the insulating isolation unit 215c. For example, the sealing member 260 may be formed of pentafluorophenyl (PFP). According to an embodiment, the surface of the sealing member 260 may not undergo hydrophobic treatment.

According to another embodiment, the lower surface of the sealing member 260 may be in direct contact with a refrigerant or CDA, and thus may undergo hydrophobic treatment. The method of performing hydrophobic treatment may be substantially the same as that described above with reference to FIG. 3.

That is, in the substrate support unit 200c of the present embodiment, the sealing member 260 may be between the electrostatic chuck 211 and the insulating isolation unit 215c. Accordingly, the electrostatic chuck 211 and the insulating isolation unit 215c are not in direct contact with each other, and thus, the electrical stability of the substrate support unit 200c may be improved.

In addition, the uppermost surface of the insulating isolation unit 215c may be positioned to be substantially coplanar with the uppermost surface among the upper surfaces of the electrostatic chuck 211. According to another embodiment, the uppermost surface of the insulating isolation unit 215c may be positioned at a lower vertical level than the lowermost surface among the upper surfaces of the electrostatic chuck 211.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate support unit comprising:
an electrostatic chuck configured to fix a wafer;
an insulating isolation unit, which is arranged below the electrostatic chuck and is configured to insulate the electrostatic chuck; and
a ground plate arranged below the insulating isolation unit,
wherein the electrostatic chuck, the insulating isolation unit, and the ground plate are spaced apart from each other in a vertical direction, and
a lower surface of the electrostatic chuck, a surface of the insulating isolation unit, or a surface of the ground plate has hydrophobicity.

2. The substrate support unit of claim 1, wherein a surface of each of the electrostatic chuck, the insulating isolation unit, or the ground plate comprises a hydrophobic structure having a roughened structure.

3. The substrate support unit of claim 2, wherein the hydrophobic structure comprises, on the surface of each of the electrostatic chuck, the insulating isolation unit, or the ground plate, sidewalls, which are perpendicular to the surface, and plateaus, which are parallel to the surface.

4. The substrate support unit of claim 3, wherein a length of the plateau in a horizontal direction is about 100 nm to about 5 μm.

5. The substrate support unit of claim 2, wherein the hydrophobic structure is formed on the surface of each of the electrostatic chuck, the insulating isolation unit, or the ground plate, through anodization.

6. The substrate support unit of claim 5, wherein the hydrophobic structure comprises at least one of aluminum oxide, copper oxide, titanium oxide, tungsten oxide, zinc oxide, and tin oxide.

7. The substrate support unit of claim 2, wherein the hydrophobic structure is formed on the surface of each of the electrostatic chuck, the insulating isolation unit, or the ground plate, by performing coating through deposition.

8. A substrate support unit comprising:
an electrostatic chuck configured to fix a wafer;
an edge ring, which surrounds the electrostatic chuck and has a ring shape;
an insulating isolation unit, which surrounds the electrostatic chuck and the edge ring and is configured to insulate the electrostatic chuck;
a sealing member arranged between a side surface of the edge ring and a side surface of the insulating isolation unit; and
a ground plate arranged below the insulating isolation unit,
wherein the electrostatic chuck, the insulating isolation unit, and the ground plate are spaced apart from each other in a vertical direction, and
a surface of the insulating isolation unit has hydrophobicity.

9. The substrate support unit of claim 8, wherein the sealing member is in direct contact with the side surface of the edge ring and the side surface of the insulating isolation unit.

10. The substrate support unit of claim 8, wherein the electrostatic chuck, the insulating isolation unit, and the ground plate are spaced apart from each other in the vertical direction to form an air gap, and
a refrigerant or clean dry air is circulated in the air gap.

11. The substrate support unit of claim 10, wherein each of the refrigerant or the clean dry air does not flow to an upper surface of the electrostatic chuck.

12. The substrate support unit of claim 8, wherein each of a lower surface of the electrostatic chuck and a side surface of the edge ring has hydrophobicity.

13. The substrate support unit of claim 8, wherein a surface of the ground plate has hydrophobicity.

14. The substrate support unit of claim 10, wherein a flow path configured to circulate the clean dry air is provided inside the air gap, and
a surface of the flow path has hydrophobicity.

15. A plasma processing apparatus comprising:
a plasma chamber;
an electrostatic chuck, which is arranged inside the plasma chamber and is configured to fix a wafer;
an edge ring, which surrounds the electrostatic chuck and has a ring shape;
an insulating isolation unit, which is arranged below the electrostatic chuck and is configured to insulate the electrostatic chuck; and
a ground plate arranged below the insulating isolation unit,
wherein the electrostatic chuck, the insulating isolation unit, and the ground plate are spaced apart from each other in a vertical direction to form an air gap,
a refrigerant or clean dry air is circulated in the air gap, and
a lower surface of the electrostatic chuck, a surface of the insulating isolation unit, and a surface of the ground plate each have hydrophobicity.

16. The plasma processing apparatus of claim 15, wherein each of the lower surface of the electrostatic chuck, the surface of the insulating isolation unit, and the surface of the ground plate has a contact angle with respect to water of 90° or greater.

17. The plasma processing apparatus of claim 15, wherein the lower surface of the electrostatic chuck, the surface of the insulating isolation unit, or the surface of the ground plate each have superhydrophobicity.

18. The plasma processing apparatus of claim 15, wherein a refrigerant flow path configured to circulate the refrigerant is provided inside the insulating isolation unit or inside the ground plate.

19. The plasma processing apparatus of claim 15, wherein the insulating isolation unit surrounds the electrostatic chuck or the edge ring,
a sealing member is arranged between a side surface of the insulating isolation unit and a side surface of the edge ring or between the side surface of the insulating isolation unit and a side surface of the electrostatic chuck, and
the sealing member is in direct contact with the side surface of the edge ring and the side surface of the insulating isolation unit.

20. The plasma processing apparatus of claim 15, wherein the side surface of the electrostatic chuck or the side surface of the edge ring each have hydrophobicity.
